(19) United States
(12) Patent Application Publication
(10) Pub. No.: US 2026/0134893 A1
(43) Pub. Date: May 14, 2026

(54) MEMORY DEVICE

(71) Applicant: Samsung Electronics Co., Ltd., Suwon-si (KR)

(72) Inventors: Kyuchang KANG, Suwon-si (KR); Changsik YOO, Suwon-si (KR); Sangyun KIM, Suwon-si (KR); Youngseok PARK, Suwon-si (KR); Younghun SEO, Suwon-si (KR); Hyunchul YOON, Suwon-si (KR)

(73) Assignee: Samsung Electronics Co., Ltd., Suwon-si (KR)

(21) Appl. No.: 19/292,337

(22) Filed: Aug. 6, 2025

(30) Foreign Application Priority Data
Nov. 14, 2024 (KR) 10-2024-0161742

(51) Int. Cl. G11C 5/06; G11C 11/408; H10B 12/00

(52) U.S. Cl. CPC G11C 5/063; G11C 11/4085; G11C 11/4087; H10B 12/485; H10B 12/488; H10B 12/50

(57) ABSTRACT

A memory device includes a first semiconductor layer including memory cells in 3-dimensions, bitlines connected to the memory cells, wordlines connected to the memory cells, main wordline select lines, inverted wordline select lines, sub-wordline select lines, ground select lines, main select transistors having a drain connected to one of the sub-wordline select lines, a source connected to one of the wordlines, and a gate connected to one of the main wordline select lines, and complementary select transistors having a drain connected to one of the wordlines, a source connected to one of the ground select lines, and a gate connected to one of the inverted wordline select lines; and a second semiconductor layer including first driver circuits driving sub-wordline select lines, second driver circuits driving the main wordline select lines, and third driver circuits driving the inverted wordline select lines. The second semiconductor layer is on the first semiconductor layer.

### CROSS-REFERENCE TO RELATED APPLICATION

This U.S. non-provisional application claims priority under 35 U.S.C. § 119 to Korean Patent Application No. 10-2024-0161742 filed on Nov. 14, 2024, in the Korean Intellectual Property Office, the disclosure of which is incorporated herein by reference in its entirety.

### BACKGROUND

Example embodiments relate to a memory device.

A memory device may include a plurality of memory cells to store data bits. A memory device may store a large amount of data while having a small area. Recently, studies are being conducted in memory devices in which memory cells are arranged three-dimensionally to improve integration density of the memory devices.

A memory device may have a peri-on-cell (PoC) or cell-on-peri (CoP) structure in which a three-dimensional memory cell structure is included in a first semiconductor layer and circuits for controlling the memory cell structure are included in a second semiconductor layer. Signal lines included in a memory cell structure may be connected to the circuits through contact structures.

### SUMMARY

Example embodiments are directed to a memory device having a reduced area.

According to some example embodiments, a memory device includes a first semiconductor layer including a plurality of memory cells in a first, second and third directions orthogonal to each other, a plurality of bitlines connected to the plurality of memory cells, a plurality of wordlines connected to the plurality of memory cells, a plurality of main wordline select lines, a plurality of inverted wordline select lines, a plurality of sub-wordline select lines, a plurality of ground select lines, a plurality of main select transistors, each of the plurality of main select transistors having a drain connected to a corresponding one of the plurality of sub-wordline select lines, a source connected to a corresponding one of the plurality of wordlines, and a gate connected to a corresponding one of the plurality of main wordline select lines, and a plurality of complementary select transistors, each of the plurality of complementary select transistors having a drain connected to a corresponding one of the plurality of wordlines, a source connected to a corresponding one of the plurality of ground select lines, and a gate connected to a corresponding one of the plurality of inverted wordline select lines; and a second semiconductor layer including a plurality of first driver circuits configured to drive sub-wordline select lines, a plurality of second driver circuits configured to drive the main wordline select lines, and a plurality of third driver circuits configured to drive the inverted wordline select lines. The second semiconductor layer is on the first semiconductor layer in the third direction.

According to some example embodiments, a memory device includes a substrate; a memory cell structure including a plurality of bitline structures extending in a vertical direction through a plurality of levels defined in the vertical direction perpendicular to an upper surface of the substrate, a plurality of memory cells in contact with sidewalls of the plurality of bitline structures at the plurality of levels, and a plurality of wordline structures extending in a first direction parallel to the upper surface of the substrate at the plurality of levels and connected to the plurality of memory cells; a plurality of first select line structures spaced apart from the plurality of wordline structures in the first direction and extending in the vertical direction; a plurality of second select line structures extending in a second direction parallel to an upper surface of the substrate and intersecting the first direction between the plurality of first select line structures and the plurality of wordline structures; a plurality of first channel structures in contact with the plurality of first select line structures and the plurality of wordline structures and penetrating the plurality of second select line structures; a plurality of third select line structures opposite to the plurality of first select line structures with respect to the plurality of wordline structures and extending in the vertical direction; a plurality of fourth select line structures extending in the second direction between the plurality of third select line structures and the plurality of wordline structures; and a plurality of second channel structures in contact with the plurality of third select line structures and the plurality of wordline structures and penetrating the fourth select line structures.

According to some example embodiments, a memory device includes a first memory cell structure including a plurality of first memory cells in a first, second and third directions orthogonal to each other, a plurality of first bitlines extending in the third direction and connected to the plurality of first memory cells, and a plurality of first wordlines extending in the first direction and connected to the plurality of first memory cells; a second memory cell structure including a plurality of second memory cells in the first direction, the second direction and the third direction, a plurality of second bitlines extending in the third direction and connected to the plurality of second memory cells, and a plurality of second wordlines extending in the first direction and connected to the plurality of second memory cells; a plurality of sub-select line structures extending in the third direction between the plurality of first wordlines and the plurality of second wordlines; a plurality of first main select line structures extending in the second direction between the plurality of first wordlines and the plurality of sub-select line structures; a plurality of second main select line structures extending in the second direction between the plurality of second wordlines and the plurality of sub-select line structures; a plurality of first channel structures penetrating the plurality of first main select line structures and connecting the plurality of first wordlines to the plurality of sub-select line structures; and a plurality of second channel structures penetrating the plurality of second main select line structures and connecting the plurality of second wordlines to the plurality of first sub-select line structures.

According to some example embodiments, a method of operating a memory device includes applying a boost voltage to a main select transistor connected to a first end of a wordline connect to a memory cell of the memory device to turn on the main select transistor. A drain of the main select transistor is connected to a sub-wordline select line, a gate of the main select transistor is connected to a main wordline select line, and a source of the main select transistor is connected to the wordline, and wherein the boost voltage is applied to the main wordline select line and the sub-wordline select line. The method further includes transferring the boost voltage of the sub-wordline select line to the wordline, and applying a ground voltage to a complementary select transistor connected to a second end opposite the first end of the wordline to turn off the complementary select transistor. A drain of the complementary select transistor is connected to the wordline, a source of the complementary select transistor is connected to a ground select line, and a gate of the complementary select transistor is connected to an inverted wordline select line. The ground voltage is applied to inverted wordline select line. According to some example embodiments, the method further includes applying the ground voltage to the main wordline select line to turn off the main select transistor, wherein the ground voltage is applied to the main wordline select line, applying the boost voltage to the inverted wordline select line to turn on the complementary select transistor, wherein the boost voltage is applied to the inverted wordline select line, and transferring the ground voltage to the wordline via the ground select line. According to some example embodiments, the first end of the wordline is connected to a first contact structure and the second end of the wordline is connected to a second contact structure, and the method further includes applying the boost voltage to the wordline through the first contact structure, and transferring the ground voltage to the wordline through the second contact structure. According to some example embodiments, the method further includes driving the sub-wordline select line using a first driver circuit, driving the main wordline select line using a second driver circuit, and driving the inverted wordline select line using a third driver circuit. According to some example embodiments, a first semiconductor layer of the memory device includes the wordline, the memory cell, the main select transistor, the complementary select transistor, the sub-wordline select line, the main wordline select line, the ground select line, and the inverted wordline select line, and a second semiconductor layer of the memory device includes the first driver circuit, the second driver circuit, and the third driver circuit.

According to some example embodiments, an electronic system includes a processor and a memory device communicably coupled to the processor. The memory device includes a first semiconductor layer including, a plurality of memory cells in a first, second and third directions orthogonal to each other, a plurality of bitlines connected to the plurality of memory cells, a plurality of wordlines connected to the plurality of memory cells, a plurality of main wordline select lines, a plurality of inverted wordline select lines, a plurality of sub-wordline select lines, a plurality of ground select lines, a plurality of main select transistors having a drain connected to a corresponding one of the plurality of sub-wordline select lines, a source connected to a corresponding one of the plurality of wordlines, and a gate connected to a corresponding one of the plurality of main wordline select lines, and a plurality of complementary select transistors having a drain connected to a corresponding one of the plurality of wordlines, a source connected to a corresponding one of the plurality of ground select lines, and a gate connected to a corresponding one of the plurality of inverted wordline select lines. The memory device also includes a second semiconductor layer including, a plurality of first driver circuits configured to drive sub-wordline select lines, a plurality of second driver circuits configured to drive the main wordline select lines, and a plurality of third driver circuits configured to drive the inverted wordline select lines. The second semiconductor layer is on the first semiconductor layer in the third direction.

### BRIEF DESCRIPTION OF DRAWINGS

The above and other aspects, features, and advantages of the present disclosure will be more clearly understood from the following detailed description, taken in combination with the accompanying drawings, in which:

FIG. 1 is a diagram illustrating a structure of a memory device according to some example embodiments.

FIG. 2 is a diagram illustrating a structure of a first semiconductor layer according to some example embodiments.

FIG. 3 is a block diagram illustrating a memory device according to some example embodiments.

FIG. 4 is a block diagram illustrating a bank array according to some example embodiments.

FIG. 5 is a diagram illustrating an example structure of a memory cell structure according to some example embodiments.

FIG. 6 is a diagram illustrating a circuit structure including wordline select lines and select transistors disposed in a first semiconductor layer according to some example embodiments.

FIGS. 7A, 7B, and 7C are diagrams illustrating driver circuits disposed in a second semiconductor layer according to some example embodiments.

FIG. 8 is a diagram illustrating a circuit of a memory cell structure according to some example embodiments.

FIG. 9 is a diagram illustrating a layout of a memory cell structure according to some example embodiments.

FIG. 10 is a cross-sectional diagram taken along line I-I′ in FIG. 9.

FIG. 11 is a diagram illustrating a memory cell structure according to some example embodiments.

FIG. 12 is a cross-sectional diagram taken along line II-II′ in FIG. 11.

FIG. 13 is a diagram illustrating a method of driving a select wordline in a memory cell structure according to some example embodiments.

FIG. 14 is a diagram illustrating a layout of a memory cell structure according to some example embodiments.

FIG. 15 illustrates an electronic system that includes a memory device according to some example embodiments.

### DETAILED DESCRIPTION

As used herein, the term “and/or” includes any and all combinations of one or more of the associated listed items. Expressions such as “at least one of,” when preceding a list of elements, modify the entire list of elements and do not modify the individual elements of the list. For example, “at least one of A, B, and C,” and similar language (e.g., “at least one selected from the group consisting of A, B, and C,” “at least one of A, B, or C”) may be construed as A only, B only, C only, or any combination of two or more of A, B, and C, such as, for instance, ABC, AB, BC, and AC.

Hereinafter, example embodiments will be described as below with reference to the accompanying drawings.

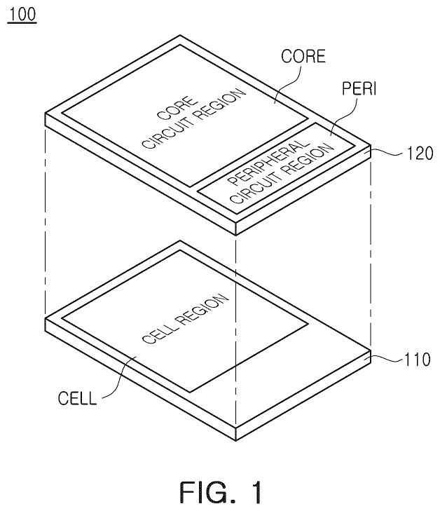

FIG. 1 is a diagram illustrating a structure of a memory device according to some example embodiments.

The memory device 100 may include a plurality of memory cells. The memory cells of the memory device, such as a dynamic random access memory (DRAM), may include a cell capacitor and a cell transistor. The cell capacitor may store a data bit by accumulating an electric charge therein, and the cell transistor may connect the cell capacitor to a bitline in response to a control signal transferred through a wordline.

To improve integration density of the memory device 100, the memory cells may be arranged three-dimensionally. In order to further reduce an area of the memory device, the memory device may include a periphery on cell (PoC) structure or a cell on periphery (CoP) structure in which a memory cell structure having memory cells arranged three-dimensionally and a circuit for controlling the memory cell structure are vertically stacked.

Referring to FIG. 1, the memory device 100 may include a first semiconductor layer 110 and a second semiconductor layer 120. The first semiconductor layer 110 may include a cell region CELL in which a plurality of memory cells are disposed. The second semiconductor layer 120 may include a core circuit region CORE including a core control circuit for controlling the memory cell structure, and a peripheral circuit region PERI including a peripheral circuit. For example, the core control circuit may include sub-wordline drivers for controlling wordlines connected to the memory cells, and a bitline sense amplifier for sensing and amplifying signals of bitlines connected to the memory cells.

The wordlines and the sub-wordline drivers may be connected through contact structures extending in a direction perpendicular to an upper surface of the first semiconductor layer 110. The wordlines may be stacked in a vertical direction in the cell region CELL. In order for each of the wordlines to be connected to the sub-wordline drivers through the contact structures, each of the wordlines may have an upper surface not overlapping the other wordlines in the vertical direction.

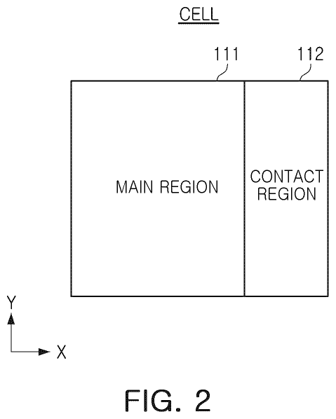

FIG. 2 is a diagram illustrating a structure of a first semiconductor layer according to some example embodiments.

The cell region CELL in FIG. 2 may correspond to the cell region CELL described with reference to FIG. 1. The cell region CELL may include a main region 111 and a contact region 112. The main region 111 may have memory cells arranged three-dimensionally, and wordlines and bitlines connected to the memory cells may be arranged. The contact region 112 may include contact structures for connecting the wordlines to sub-wordline drivers. Although, FIG. 2 illustrates a single main region 111 and a single contact region 112, the cell region CELL may have a plurality of main regions and a plurality of contact regions.

To increase integration density of the memory cells, the wordlines may be stacked in multiple layers. However, when each wordline may have an upper surface not overlapping other wordlines, an area of the region occupied by the contact structures in the cell region CELL may increase as the number of stacked wordlines increases. Accordingly, a ratio of the area occupied by the contact region 112 in the cell region CELL may increase, and integration efficiency of the memory cells may decrease.

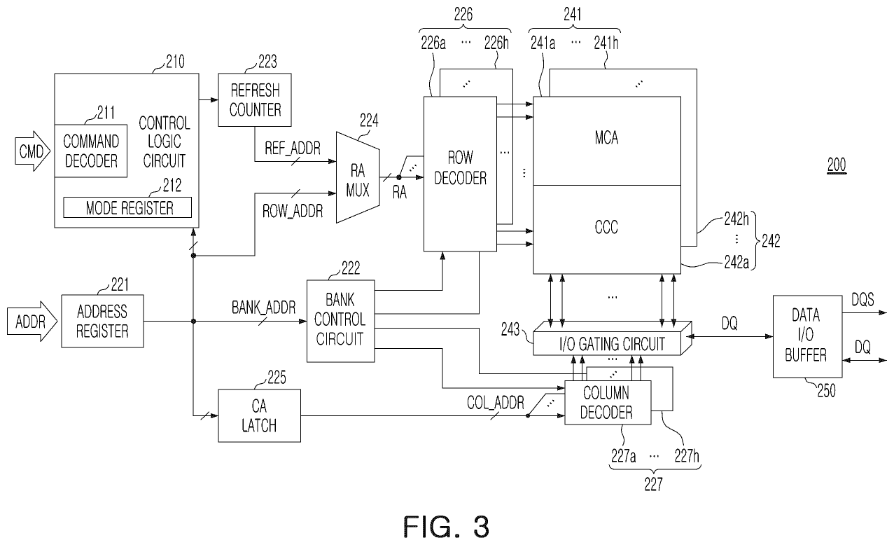

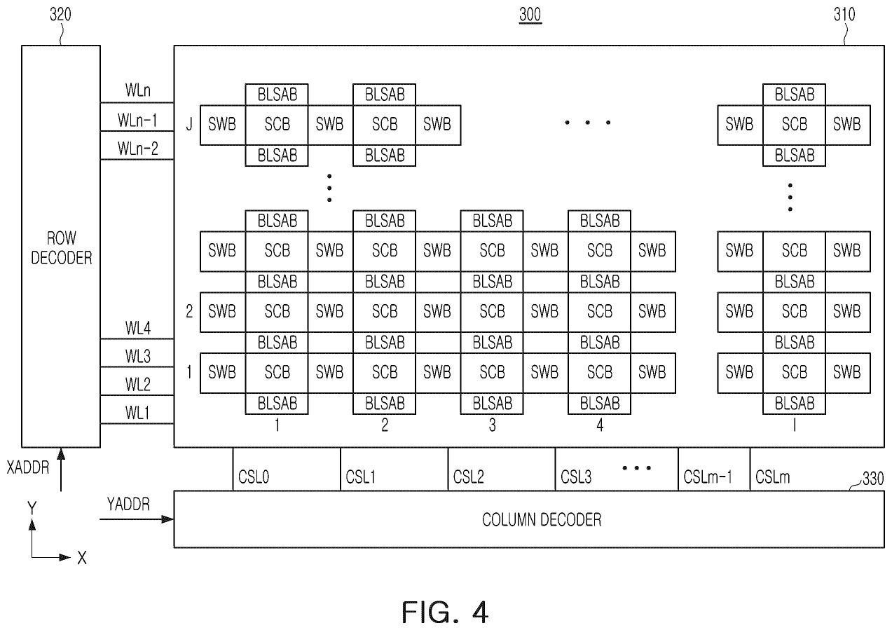

According to some example embodiments, a memory device may include memory cells that may be further integrated by reducing the size of the contact region 112. Before describing the structure of the memory device according to some example embodiments in detail, the circuit structure of the memory device may be described with reference to FIGS. 3 and 4.

FIG. 3 is a block diagram illustrating a memory device according to some example embodiments.

Referring to FIG. 3, a memory device 200 may include a control logic circuit 210, an address register 221, a bank control circuit 222, a refresh counter 223, a row address multiplexer 224, a column address latch 225, a row decoder 226, a column decoder 227, a bank array 241, a sense amplifier 242, an input/output gate circuit 243, and/or a data input/output buffer 250.

Similarly to the memory device 100 described with reference to FIG. 1, the memory device 200 may include a first semiconductor layer and a second semiconductor layer disposed in a vertical direction. The bank array 241 may be formed in a cell region of the first semiconductor layer, and the control logic circuit 210 and the sense amplifier 242 may be formed in the core circuit region of the second semiconductor layer. The address register 221, the bank control circuit 222, the refresh counter 223, the row address multiplexer 224, the column address latch 225, the row decoder 226, the column decoder 227, the input/output gate circuit 243 and/or the data input/output buffer 250 may be included in a peripheral circuit region of the second semiconductor layer.

The control logic circuit 210 may control operation of the memory device 200. For example, the control logic circuit 210 may generate control signals for the memory device 200 to perform a write operation and/or a readout operation. The control logic circuit 210 may include a command decoder 211 for decoding a command CMD received from the memory controller (e.g., an external memory controller) and a mode register 212 for setting an operation mode of the memory device 200.

For example, the command decoder 211 may decode a write enable signal, a row address strobe signal, a column address strobe signal, a chip select signal, or the like, and may generate control signals corresponding to the command CMD.

The bank array 241 may include a plurality of bank arrays 241a-241h. Also, a plurality of row decodes 226 (226a-226h), and a plurality of column decoders 227 (227a-227h) may be connected to a plurality of bank arrays 241a-241h, respectively.

Each bank array 241a-241h, column decoder 227a-227h, and row decoder 226a-226h may define or may be included in a bank. Thus, the memory device 200 may include a plurality of banks each including a corresponding one of bank arrays 241a-241h, column decoders 227a-227h, and row decoders 226a-226h.

Each of the plurality of bank arrays 241a-241h may include a memory cell array MCA and a core control circuit CCC. The memory cell array MCA may be positioned in the first semiconductor layer, and the core control circuit CCC may be located in the second semiconductor layer and may overlap the memory cell array MCA in the vertical direction.

The memory cell array MCA may include a plurality of wordlines, a plurality of bitlines, and a plurality of memory cells connected to the plurality of wordlines and the plurality of bitlines.

The core control circuit CCC may include circuits for controlling the memory cell array MCA. For example, the core control circuit CCC may include a sub-wordline driver circuit for driving the plurality of wordlines and a bitline sense amplifier circuit for sensing voltage changes of the plurality of bitlines and amplifying the voltage changes.

The address register 221 may receive an address ADDR including a bank address BANK_ADDR, a row address ROW_ADDR and a column address COL_ADDR from a memory controller connected to the memory device 200. The address register 221 may provide the received bank address BANK_ADDR to the bank control circuit 222, may provide the received row address ROW_ADDR to the row address multiplexer 224, and may provide the received column address COL_ADDR to the column address latch 225.

The bank control circuit 222 may generate bank control signals in response to the bank address BANK_ADDR. In response to the bank control signals, a row decoder corresponding to the bank address BANK_ADDR among the plurality of row decoders 226a-226h may be activated, and a column decoder corresponding to the bank address BANK_ADDR among the plurality of column decoders 227a-227h may be activated.

The row address multiplexer 224 may receive the row address ROW_ADDR from the address register 221 and the refresh row address REF_ADDR from the refresh counter 223. The row address multiplexer 224 may selectively output the row address ROW_ADDR or the refresh row address REF_ADDR as the row address RA. The row address RA output from the row address multiplexer 224 may be applied to each of the plurality of row decoders 226a-226h.

The refresh counter 223 may sequentially increase or decrease the refresh row address REF_ADDR under control of the control logic circuit 210.

Among the plurality of row decoders 226a-226h, the row decoder activated by the bank control circuit 222 may decode the row address RA output from the row address multiplexer 224 and may activate the wordline corresponding to the row address. For example, the activated row decoder may apply the wordline driving voltage to the wordline corresponding to the row address.

The column address latch 225 may receive the column address COL_ADDR from the address register 221 and may temporarily store the received column address COL_ADDR. Also, the column address latch 225 may incrementally increase the received column address COL_ADDR in a burst mode. The column address latch 225 may apply a column address COL_ADDR, temporarily stored or incrementally increased, to each of the plurality of column decoders 227a-227h.

Among the plurality of column decoders 227a-227h, a column decoder activated by the bank control circuit 222 may activate a sense amplifier corresponding to the bank address BANK_ADDR and the column address COL_ADDR through a corresponding input/output gate circuit 243.

The input/output gating circuit 243 may include circuits for gating input/output data, input data mask logic, readout data latches for storing data output from the plurality of bank arrays 241a-241h, and write drivers for writing data to the plurality of bank arrays 241a-241h.

A data signal DQ to be read out from one of the plurality of bank arrays 241a-241h may be sensed by a sense amplifier corresponding to the one of the bank arrays and stored in the readout data latches. The data signal DQ stored in the readout data latches may be provided to a memory controller together with a data strobe signal DQS.

A data signal DQ to be written to a memory cell array MCA included in one of the plurality of bank arrays 241a-241h may be provided to an input/output gating circuit 243 by a data input/output buffer 250. The input/output gating circuit 243 may write the data signal DQ to a target page of the one of the memory cell array MCA through the write drivers.

The data input/output buffer 250 may provide a data signal DQ to the input/output gating circuit 243 in a write operation, and may provide a data signal DQ provided from the input/output gating circuit 243 to the memory controller in a read operation.

Each of the plurality of bank arrays 241a-241h may include a plurality of sub-cell arrays to reduce the loading capacitance of wordlines, and may have a structure in which each of the memory cells of the sub-cell arrays may be connected to a plurality of wordlines. Hereinafter, the structure of the bank array may be described with reference to FIG. 4.

FIG. 4 is a block diagram illustrating a bank array according to some example embodiments.

The memory device 300 may be similar to the memory devices 100 and 200, discussed above with reference to FIGS. 1 and 2. The memory device 300 illustrated in FIG. 4 may include a bank array 310, a row decoder 320, and a column decoder 330. The bank array 310, the row decoder 320, and the column decoder 330 in FIG. 4 may correspond to the bank array 241, the row decoder 226, and the column decoder 227 described with reference to FIG. 3.

The bank array 310 may include an I number of sub-array blocks SCB in the first direction X and J sub-array blocks SCB in the second direction Y. In each of the sub-array block SCB, a plurality of wordlines WL extending in the first direction X, a plurality of bitlines BL extending in the second direction Y, and memory cells positioned at points at which the plurality of wordlines WL and the plurality of bitlines BL intersect may be disposed. One memory block BLK0, BLK1, and BLK2 may include at least one sub-array block.

An I+1 number of the sub-wordline driver regions SWB may be disposed adjacent and/or between sub-array blocks SCB disposed in the first direction X. In the sub-wordline driver region SWB, sub-wordline drivers may be disposed.

A J+1 number of the bitline sense amplifier regions BLSAB may be disposed adjacent and/or between the sub-array blocks SCB disposed in the second direction Y. In the bitline sense amplifier region BLSAB, a plurality of bitline sense amplifiers may be disposed.

The sub-wordline driver region SWB and the bitline sense amplifier region BLSAB in the bank array 310 may be disposed in the core circuit region CCC described with reference to FIG. 2. For example, the sub-wordline driver region SWB and the bitline sense amplifier region BLSAB may vertically overlap each other in the sub-array block SCB.

The row decoder 320 may receive a row address signal XADDR from a control logic circuit. The row decoder 320 may output a driving voltage to a wordline WLi (i is a natural number less than or equal to n) corresponding to a row to be activated in the bank array 310 through a plurality of wordlines WL extending in the first direction X.

The column decoder 330 may receive a column address signal YADDR from the control logic circuit. The column decoder 330 may output a column select signal to a bitline BLj (j is a natural number less than or equal to m) corresponding to a column to be activated in the bank array 310 through a plurality of column select lines CSL1-CSLm extending in the second direction Y.

The sub-array block SCB may include one or more memory cell structures.

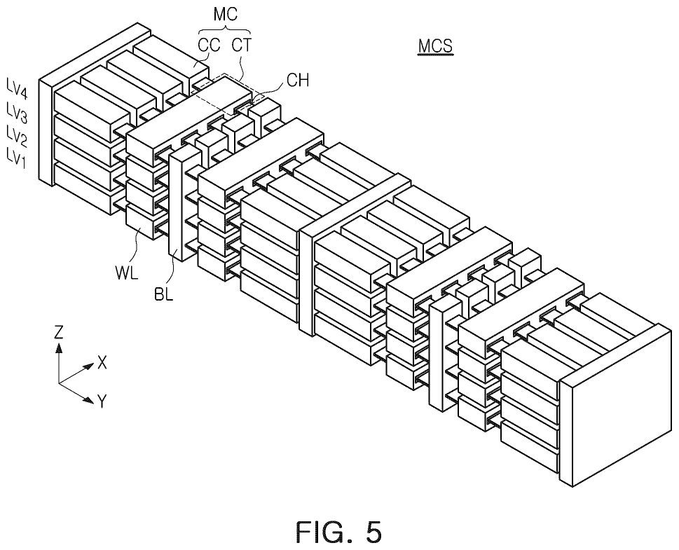

FIG. 5 is a diagram illustrating an example structure of a memory cell structure according to some example embodiments.

The first direction X and the second direction Y may be parallel to an upper surface of the substrate and may intersect each other. The third direction Z may be a direction perpendicular to an upper surface of the substrate. In FIG. 5, the substrate is not illustrated for the sake of clarity of illustration, but the memory cell structure MCS may be formed on an upper portion of the substrate.

The memory cell structure MCS may include a plurality of bitline structures BL arranged in the first direction X and the second direction Y and extending in the third direction Z, a plurality of wordline structures WL arranged in the second direction Y and the third direction Z and extending in the first direction X, and a plurality of memory cells MC connected to the bitline structures BL and the wordline structures WL.

A plurality of memory cells MC may be arranged in the first direction X, the second direction Y, and the third direction Z. Particularly, the plurality of memory cells MC may be arranged in each of the plurality of levels LV1-LV4 in the third direction Z.

The plurality of memory cells MC may be in contact with a sidewall of bitline structures BL (for example, at the plurality of levels LV1-LV4). For example, in each of the plurality of levels LV1-LV4, a pair of memory cells MC may be disposed to face each other in the second direction Y with respect to one bitline structure BL. In some example embodiments, one bitline structure BL may be connected to multiple pairs of memory cells MC.

Each of the memory cells MC may include a cell capacitor CC and a cell transistor CT. The cell capacitor CC may store electric charges corresponding to a data bit. The cell transistor CT may electrically connect the cell capacitor CC to the bitline structure BL.

The cell transistor CT may include a channel structure CH in contact with the wordline structure WL, and a region in contact with the channel structure CH in the wordline structure WL. For example, the cell transistor CT may have a gate all around (GAA) structure having the channel structure CH surrounded by the wordline structure WL. Since the channel structure CH of the cell transistor CT may be separated from the substrate, the plurality of cell transistors may be vertically stacked on the substrate.

The channel structure CH may include impurity regions of which at least a portion is exposed externally of the wordline structure WL, and a channel region surrounded by the wordline structure WL. For example, the impurity regions may be doped with N-type impurities, and the channel region may be doped with P-type impurities. The impurity regions may provide a source and a drain. For example, the first impurity region may be connected to a bitline, and the second impurity region may be connected to a cell capacitor CC.

The wordline structure WL may include a gate insulating layer surrounding the channel structure CH, and a wordline electrode surrounding the gate insulating layer. The wordline electrode may provide a wordline. For example, when a voltage greater than a threshold voltage is applied to the wordline electrode, a channel may be formed in the channel region, and the bitline BL and the cell capacitor CC may be electrically connected to each other.

The channel structure CH may extend in the second direction Y. The wordline structure WL may extend in the first direction X (for example, at the plurality of levels LV1-LV4), and may be shared by a plurality of cell transistors CT arranged in the first direction X.

The memory device may include sub-wordline drivers for driving wordlines included in the memory cell structure. For example, the sub-wordline drivers may activate the wordline by driving the wordline with boost voltage VPP, or may deactivate the wordline by driving the wordline with ground voltage VSS.

According to some example embodiments, the memory device may select a portion of the wordlines based on two or more types of wordline select signals. Selected lines for transferring the wordline select signals may be disposed in a first semiconductor layer including the memory cell structure, and the selected lines may be connected to driver circuits in a second semiconductor layer.

According to some example embodiments, the number of contact structures for connecting driver circuits for driving the wordlines to the wordlines may be reduced, and the area of the contact region may be reduced. Accordingly, integration efficiency of the memory device may be increased or improved.

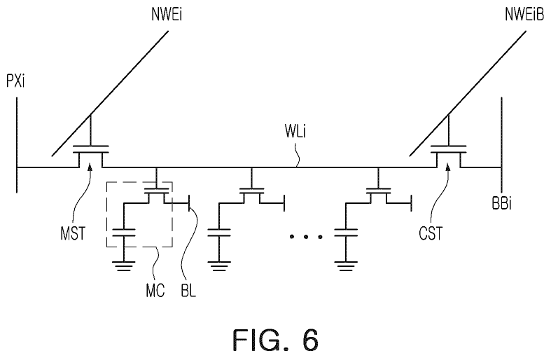

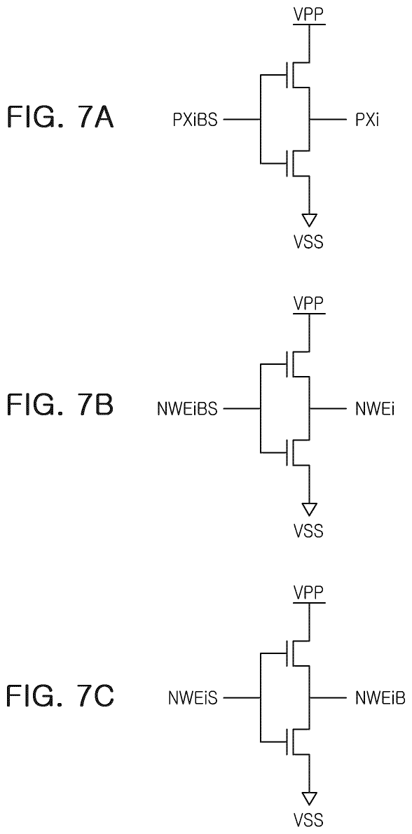

Hereinafter, a circuit structure of a sub-wordline driver according to some example embodiments may be described with reference to FIG. 6 and FIGS. 7A to 7C.

A sub-wordline driver according to some example embodiments may include wordline select lines and select transistors formed in a first semiconductor layer, and driver circuits formed in a second semiconductor layer.

FIG. 6 is a diagram illustrating a circuit structure including wordline select lines and select transistors disposed in a first semiconductor layer according to some example embodiments.

FIG. 6 illustrate circuits connected to wordline WLi.

The wordline WLi may correspond to one of the wordlines provided by the wordline structures WL described with reference to FIG. 5. The plurality of memory cells MC may be connected to the wordline WLi. When the wordline WLi is driven with boost voltage VPP, cell transistors of the plurality of memory cells MC connected to the wordline WLi may be turned on. When the wordline WLi is driven with ground voltage VSS, the cell transistors may be turned off.

Wordline WLi may be driven with boost voltage VPP by a main wordline select signal and a sub-wordline select signal, and may be driven with ground voltage VSS by an inverted wordline select signal. FIG. 6 may illustrate a main wordline select line NWEi transferring a main wordline select signal, an inverted wordline select line NWEiB transferring an inverted wordline select signal, a sub-wordline select line PXi transferring a sub-wordline select signal, and a ground select line BBi providing a ground voltage VSS.

A main select transistor MST and a complementary select transistor CST may be connected to opposite ends of the wordline WLi. The main select transistor MST may include a drain connected to the sub-wordline select line PXi, a source connected to the wordline WLi, and a gate connected to the main wordline select line NWEi. The complementary select transistor CST may include a drain connected to the wordline WLi, a source connected to the ground select line BBi, and a gate connected to the inverted wordline select line NWEiB.

In order for wordline WLi to be driven by the boost voltage VPP, the main wordline select line NWEi and the sub-wordline select line PXi may be driven by the boost voltage VPP, and the inverted wordline select line NWEiB may be driven by the ground voltage VSS. When the main wordline select line NWEi and the sub-wordline select line PXi are driven by the boost voltage VPP, the main select transistor MST may be turned on, and the boost voltage VPP of the sub-wordline select line PXi may be transferred to the wordline WLi. When the inverted wordline select line NWEiB is driven by the ground voltage VSS, the complementary select transistor CST may be turned off, and the connection between wordline WLi and the ground select line BBi may be disconnected.

In order for wordline WLi to be driven with the ground voltage VSS, the main wordline select line NWEi may be driven with the ground voltage VSS, and the inverted wordline select line NWEiB may be driven with boost voltage VPP. When the main wordline select line NWEi is driven with the ground voltage VSS, the main select transistor MST may be turned off, and connection between the sub-wordline select line PXi and the wordline WLi may be disconnected. When the inverted wordline select line NWEiB is driven with the boost voltage VPP, the complementary select transistor CST may be turned on, and the ground voltage VSS may be transferred to the wordline WLi. The sub-wordline select line PXi may have the boost voltage VPP or the ground voltage VSS.

The driver circuits for driving the main wordline select line NWEi, the inverted wordline select line NWEiB, and the sub-wordline select line PXi may be disposed in the second semiconductor layer.

FIGS. 7A to 7C are diagrams illustrating driver circuits disposed in a second semiconductor layer according to some example embodiments.

FIG. 7A illustrates a first driver circuit for driving a sub-wordline select line PXi, FIG. 7B illustrates a second driver circuit for driving a main wordline select line NWEi, and FIG. 7C illustrates a third driver circuit for driving an inverted wordline select line NWEiB.

In some example embodiments, each of the first to third driver circuits may be implemented as an inverter circuit. Referring to FIG. 7A, the first driver circuit may drive the sub-wordline select line PXi with boost voltage VPP when the inverted sub-wordline select signal PXiBS is at a logic low level, and may drive the sub-wordline select line PXL with ground voltage VSS when the inverted sub-wordline signal PXiBS is at a logic high level.

Referring to FIG. 7B, the second driver circuit may drive the main wordline select line NWEi with the boost voltage VPP when the inverted wordline select signal NWEiBS is at the logic low level, and may drive the main wordline select line NWEi with the ground voltage VSS when the inverted wordline select signal NWEiBS is at the logic high level.

Referring to FIG. 7C, the third driver circuit may drive the inverted wordline select line NWEiB with the boost voltage VPP when the main wordline select signal NWEiS is at the logic low level, and may drive the inverted wordline select line NWEiB with the ground voltage VSS when the main wordline select signal NWEiS is at the logic high level.

The select lines may be disposed in the first semiconductor layer on which the memory cell structure is disposed, and the select lines may be connected to the driver circuits disposed in the second semiconductor layer through contact structures.

According to some example embodiments, when select wordlines are connected to driver circuits through contact structures, an area of the contact region may be reduced, and the number of driver circuits may be reduced as compared to when each wordline is connected to a sub-wordline driver through contact structures. Accordingly, the area of the memory device may be reduced.

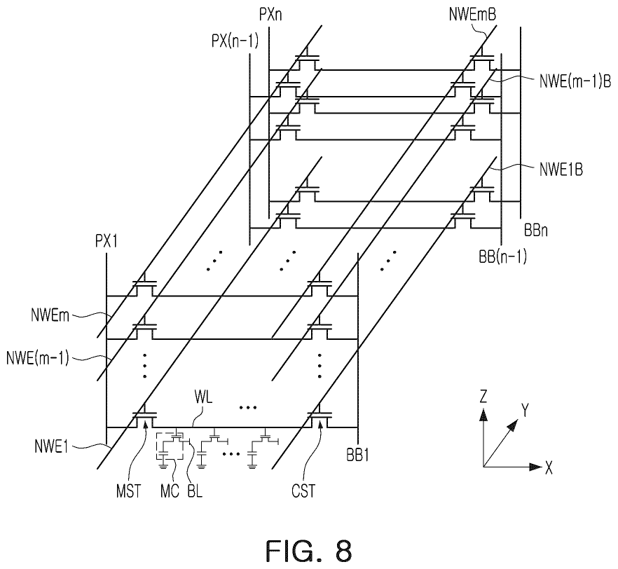

Hereinafter, the arrangement structure of wordlines and select lines in the first semiconductor layer may be described with reference to FIG. 8.

FIG. 8 is a diagram illustrating a circuit of a memory cell structure according to some example embodiments.

Referring to FIG. 8, the memory cell structure may include a plurality of memory cells MC, a plurality of wordlines WL, a plurality of main wordline select lines NWE1-NWEm, a plurality of complementary wordline select lines NWEB1-NWEBmB, a plurality of sub-wordline select lines PX1-PXn, and a plurality of ground select lines BB1-BBn.

A plurality of wordlines WL may extend in the first direction X and may be arranged in the second direction Y and the third direction Z. A main select transistor MST and a complementary select transistor CST may be disposed on opposite ends of each of the plurality of wordlines WL.

The plurality of main wordline select lines NWE1-NWEm and the inverted wordline select lines NWE1B-NWEmB may be arranged in the third direction Z and may extend in the second direction Y. A plurality of sub-wordline select lines PX1-PXn and a plurality of ground select lines BB1-BBn may be arranged in the second direction Y and may extend in the third direction Z.

Among the plurality of wordlines WL, wordlines arranged in the second direction Y may be connected to one main wordline select line and one inverted wordline select line. Among the plurality of wordlines WL, wordlines arranged in the third direction Z may be connected to one sub-wordline select line and one ground select line.

The plurality of sub-wordline select lines PX1-PXn may be connected to first driver circuits as described with reference to FIG. 7A, the plurality of main wordline select lines NWE1-NWEm may be connected to second driver circuits as described with reference to FIG. 7B, and the inverted wordline select lines NWE1B-NWEmB may be connected to third driver circuits as described with reference to FIG. 7C.

A row decoder 320 as described with reference to FIG. 4 may decode the first bits of a row address signal XADDR as main wordline select signals and inverted wordline select signals, and may decode the second bits of the row address signal XADDR as sub-wordline select signals. In some example embodiments, the row decoder 320 may be configured to drive the selected wordlines with a boost voltage and may be configured to drive non-selected wordlines with a ground voltage. The row decoder 320 may be configured to drive the selected sub-wordline select lines with a boost voltage and may be configured to drive the non-selected sub-wordline select lines with a ground voltage by controlling the first driver circuits using the sub-wordline select signals. The row decoder 320 may be configured to drive the selected main wordline select lines with the boost voltage and may be configured to drive the non-selected main wordline select lines with the ground voltage by controlling the second driver circuits using the inverted wordline select signals. The row decoder 320 may be configured to drive the selected inverted wordline select lines with the boost voltage and may be configured to drive the non-selected inverted wordline select lines with the ground voltage by controlling the third driver circuits using the main wordline select signals.

According to some example embodiments, since a wordline may be selected using two types of select signals including a main wordline select signal and a sub-wordline select signal, the number of select lines may be reduced as compared to the number of wordlines. For example, to select one of 1024 wordlines, 6 bits of the 10-bit row address may be decoded into a main wordline select signal and 4 bits of the address may be decoded into a sub-wordline select signal. To select one of 1024 wordlines, 160 select lines including 64 main wordline select lines, 64 inverted wordline select lines, 16 sub-wordline select lines, and 16 ground select lines may be used.

Since the number of select lines may be smaller than the number of wordlines, the number of contact structures for connecting select lines and driver circuits may also be smaller than the number of wordlines, and integration efficiency of the memory device may be increased.

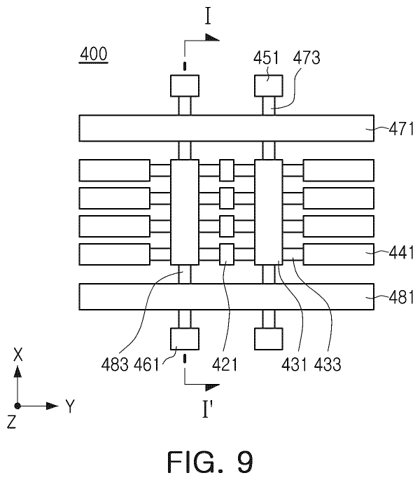

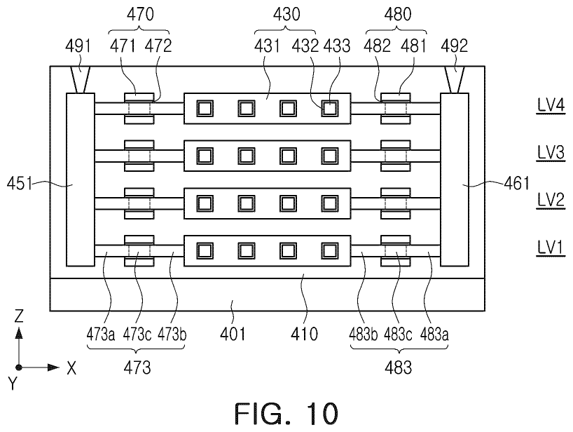

Hereinafter, a specific structure of a memory cell structure according to some example embodiments may be described with reference to FIGS. 9 and 10.

FIG. 9 is a diagram illustrating a layout of a memory cell structure according to some example embodiments. FIG. 10 is a cross-sectional diagram taken along line I-I′ in FIG. 9.

Referring to FIGS. 9 and 10 together, a memory cell structure 400 may include a substrate 401, an insulating layer 410, bitline structures 421, wordline structures 430, first channel structures 433, cell capacitors 441, a sub-select line structure 451, a ground select line structure 461, main select line structures 470, second channel structures 473, inverted select line structures 480, third channel structures 483, and first and second contact structures 491, 492.

As described with reference to FIG. 5, the bitline structures 421 may extend in the third direction Z and may be arranged in the first direction X and the second direction Y. FIG. 9 may illustrate the bitline structures 421 arranged in the first direction X. The bitline structures 421 may correspond to the bitlines BL in FIG. 8.

The wordline structures 430 may be disposed to extend in the first direction X and to be spaced apart from the bitline structures 421 in the second direction Y. The wordline structures 430 may include the wordline electrode 431 and the gate insulating layer 432. The wordline structures 430 may correspond to the wordlines WL in FIG. 8.

The cell capacitors 441 may be spaced apart from the wordline structures 430 in the second direction Y.

The first channel structures 433 may penetrate the wordline structures 430 and may be in contact with the bitline structures 421 and the cell capacitors 441. The plurality of first channel structures 433 may be formed penetrating one wordline structure 430 and spaced apart from each other in the first direction X. The gate insulating layer 432 may surround the first channel structure 433, and the wordline electrode 431 may surround the gate insulating layer 432. The first channel structures 433 may include a first impurity region in contact with the cell capacitor 441, a second impurity region in contact with the bitline structure 421, and a channel region surrounded by the gate insulating layer 432. The region surrounding the gate insulating layer 432 in the wordline electrode 431, the gate insulating layer 432 and the first channel structure 433 may provide or form a cell transistor.

According to some example embodiments, the sub-select line structures 451 and the ground select line structures 461 may extend in the third direction Z and may be spaced apart from the wordline structures 430 in the first direction X. The sub-select line structures 451 and the ground select line structures 461 may be disposed in opposite directions with respect to the wordline structures 430. The sub-select line structures 451 may correspond to the sub-wordline select lines PX1-PXn in FIG. 8, and the ground select line structures 461 may correspond to the ground select lines BB1-BBn in FIG. 8. For example, the sub-select line structures 451 may be connected to the first driver circuits in FIG. 7A, and the ground select line structures 461 may be connected to the ground power supply.

A plurality of main select line structures 470 extending in the second direction Y and arranged in the third direction Z may be disposed between the wordline structures 430 and the sub-select line structures 451. A plurality of inverted select line structures 480 extending in the second direction Y and arranged in the third direction Z may be disposed between the wordline structures 430 and the ground select line structures 461.

Each of the main select line structures 470 may include a main select line electrode 471 and a second gate insulating layer 472. A plurality of second channel structures 473 may penetrate the main select line structures 470, respectively. The second channel structures 473 may include a first impurity region 473a in contact with the sub-select line structure 451, a second impurity region 473b in contact with the wordline structure 430, and a channel region 473c surrounded by the second gate insulating layer 472.

The main select line electrodes 471 may correspond to the main select line wordlines NWE1-NWEm in FIG. 8. The region surrounding the second gate insulating layer 472 in the main select line electrode 471, the second gate insulating layer 472, and the second channel structure 473 may provide the main select transistor MST in FIG. 8. For example, the main select line electrodes 471 may be connected to the second driver circuits in FIG. 7B.

Each of the inverted select line structures 480 may include an inverted select line electrode 481 and a third gate insulating layer 482. A plurality of third channel structures 483 may penetrate each of the inverted select line structures 480. The third channel structures 483 may include a first impurity region 483a in contact with the ground select line structure 461, a second impurity region 483b in contact with the wordline structure 430, and a channel region 483c surrounded by the third gate insulating layer 482.

The inverted select line electrodes 481 may correspond to the inverted select line wordlines NWE1B-NWEmB in FIG. 8. The region surrounding the third gate insulating layer 482 in the inverted select line electrode 481, the third gate insulating layer 482, and the third channel structure 483 may provide the complementary select transistor CST in FIG. 8. For example, the inverted select line electrodes 481 may be connected to the third driver circuits in FIG. 7C.

In some example embodiments, the second channel structures 473 and the third channel structures 483 may have the same size and the same shape as those of the first channel structure 433. For example, the first to third channel structures 433, 473, and 483 may have a GAA structure.

The insulating layer 410 may cover the bitline structures 421, the wordline structures 430, the first channel structures 433, the cell capacitors 441, the sub-select line structure 451, the ground select line structure 461, the main select line structures 470, the second channel structures 473, the inverted select line structures 480, and/or the third channel structures 483 on an upper portion (e.g., an upper surface) of the substrate 401.

The first contact structures 491 may be disposed on an upper surface of the sub-select line structure 451 (for example, in a plane parallel to the upper surface of the substrate) and may be exposed from an upper surface of the insulating layer 410. The first contact structures 491 may electrically connect the sub-select line structure 451 to the first driver circuit described with reference to FIG. 7A. The second contact structures 492 may be disposed on an upper surface of the ground select line structure 461 and may be exposed from an upper surface of the insulating layer 410. The second contact structures 492 may connect the ground select line structure 461 to the ground power supply.

According to some example embodiments, the wordlines may be connected to driver circuits of the second semiconductor layer through the main select transistor MST, the complementary select transistor CST, the sub-wordline select line, and the ground select line connected to the wordlines. Accordingly, the number of contact structures required for the memory cell structure 400 may be reduced as compared to the example in which the driver circuits of the second semiconductor layer are connected to the wordlines of the first semiconductor layer.

Referring to FIG. 10, the wordline structures 430 disposed in each of the plurality of levels LV1-LV4 defined in the third direction Z may have substantially the same length and may have upper surfaces not overlapping or offset from each other. In some example embodiments, at least a portion of the wordline structures 430 may have a same length. Accordingly, even when the number of wordlines stacked in the third direction Z increases, the length of the wordlines in the first direction X may not increase.

The main select line electrodes 471 and the inverted select line electrodes 481 may be stacked in the third direction Z, respectively, and contact structures may be connected to each other for electrical connection to driver circuits of the second semiconductor layer. Accordingly, the main select line electrodes 471 may have upper surfaces not overlapping or offset from each other in the third direction Z, and the inverted select line electrodes 481 may have upper surfaces not overlapping or offset from each other in the third direction Z.

However, since the number of the main select line electrodes 471 and the inverted select line electrodes 481 may be less than the number of the wordline structures 430, the area of the contact region may be reduced, and the contact structures in the first semiconductor layer may be efficiently disposed.

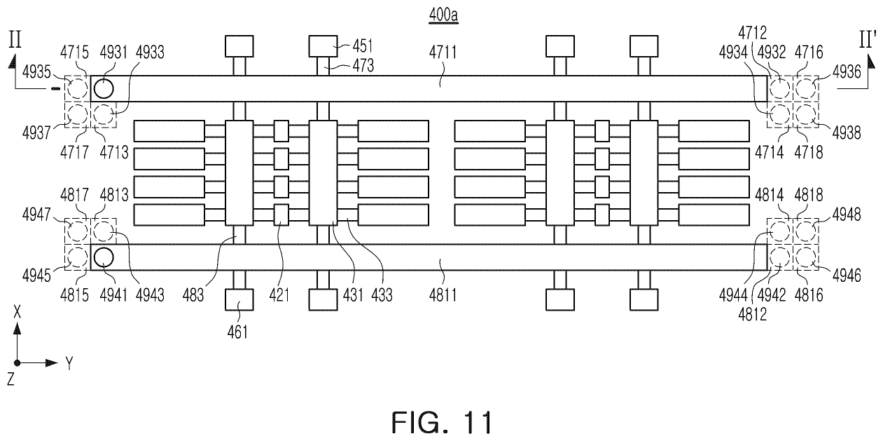

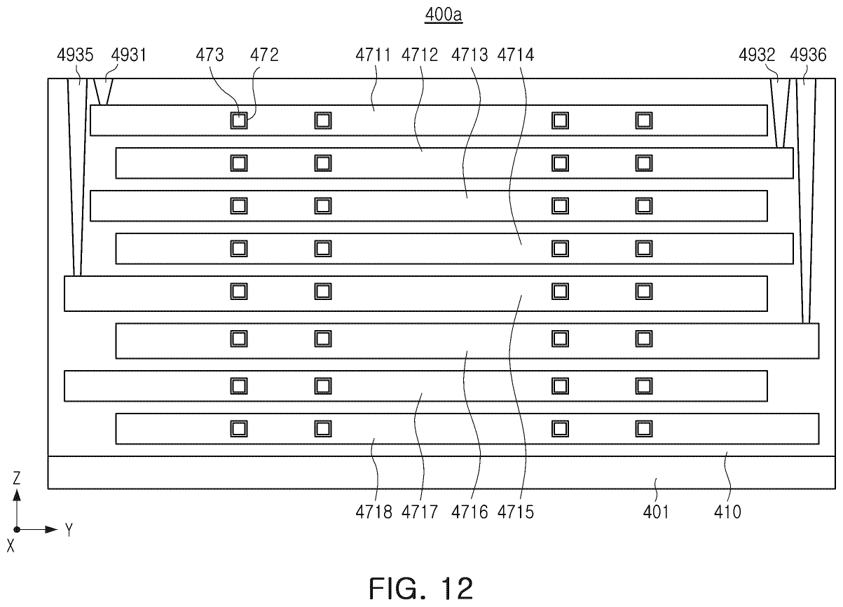

Hereinafter, the arrangement structure of the contact structures connected to the main select line electrodes 471 and the inverted select line electrodes 481 may be described with reference to FIGS. 11 and 12.

FIG. 11 is a diagram illustrating a memory cell structure 400a according to some example embodiments.

FIG. 11 may illustrate a memory cell structure 400a including memory cells disposed on eight levels defined in the third direction Z. The memory cell structure 400a may have a structure in which the unit structures (e.g., unit memory cell structures 400) are disposed in the second direction Y, with the memory cell structure 400 described with reference to FIGS. 9 and 10 as a unit structure.

The main select line electrodes 4711-4718 and the inverted select line electrodes 4811-4818 may extend in the second direction Y and may be disposed on each of a plurality of levels defined in the third direction Z. In FIG. 11, eight levels may be defined in the third direction Z, and eight main select line electrodes 4711-4718 and inverted select line electrodes 4811-4818 may be disposed, but the number of levels is not limited thereto. Among the eight levels, the first main select line electrode 4711 and the first inverted select line electrode 4811 disposed on the uppermost level may be illustrated with solid lines, and the main select line electrodes 4712-4718 and inverted select line electrodes 4812-4818 disposed on the other levels may be illustrated with dashed lines.

According to some example embodiments, the main select line electrodes 4711-4718 and the inverted select line electrodes 4811-4818 may include upper surfaces that may not overlap (e.g., may not entirely overlap, or may not be vertically coincident) each other in the third direction Z. Third contact structures 4931-4938 may be disposed on upper surfaces of the main select line electrodes 4711-4718 that may not overlap each other. The third contact structures 4931-4938 may connect the main select line electrodes 4711-4718 to the second driver circuits described with reference to FIG. 7B.

Fourth contact structures 4941-4948 may be disposed on upper surfaces of the inverted select line electrodes 4811-4818 that may not overlap each other. The fourth contact structures 4941-4948 may connect the inverted select line electrodes 4811-4818 to third driver circuits described with reference to FIG. 7C.

In some example embodiments, the upper surfaces may be disposed in the first direction X and the second direction Y. That is, at least some of the main select line electrodes 4711-4718 and the inverted select line electrodes 4811-4818 may be L-shaped in which ends are bent. The third contact structures 4931-4938 and the fourth contact structures 4941-4948 may be disposed in the first direction X and the second direction Y on an upper portion of the upper surfaces.

FIG. 12 is a cross-sectional diagram taken along line II-II′ in FIG. 11.

Referring to FIG. 12, a memory cell structure 400a may include the substrate 401 and the insulating layer 410. FIG. 12 may illustrate a plurality of main select line electrodes 4711-4718, second gate insulating layers 472, second channel structures 473 and a plurality of contact structures 4931, 4932, 4935, and 4936 disposed in the insulating layer 410. The other contact structures 4933, 4934, 4937, and 4938 illustrated in FIG. 11 may be disposed in the same positions in the second direction Y as the respective contact structures 4931, 4932, 4935, and 4936 and in different positions in the first direction X.

When ends of at least some of the main select line electrodes 4711-4718 and the inverted select line electrodes 4811-4818 have a bent shape, the memory cell structure 400a may be disposed more area-efficiently than when the main select line electrodes 4711-4718 and the inverted select line electrodes 4811-4818 uniformly extend in the second direction Y and are disposed in a staircase shape.

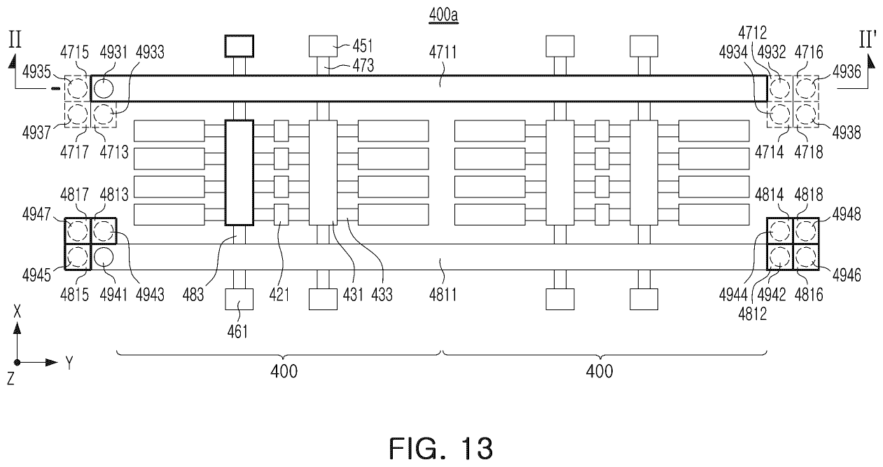

FIG. 13 is a diagram illustrating a method of driving a selected wordline in a memory cell structure 400a according to some example embodiments.

The layout in FIG. 13 may be the same as or similar in some respects to the layout in FIG. 11. However, in FIG. 13, among the plurality of wordline electrodes 431, the electrode corresponding to the selected wordline is illustrated with a bold line, and when the selected wordline is driven with a boost voltage, select line structures having a logic high level may be illustrated with a bold line.

As described with reference to FIG. 6, in order to drive the selected wordline with boost voltage VPP, the sub-wordline select line PXi connected to the selected wordline may be driven with a boost voltage VPP, the main select transistor MST may be turned on, and the complementary select transistor CST may be turned off.

In the example in FIG. 13, among the plurality of contact structures 4931-4938, the contact structures 4931 connected to the selected wordline may have a logic high level, and the other contact structures 4932-4938 may have a logic low level. When the contact structures 4931 has a logic high level, the main select transistors MST connected to the wordline electrodes of the uppermost level may be turned on.

Among the plurality of sub-select line structures 451, the sub-select line structure 451 connected to the selected wordline may have a logic high level, and the other sub-select line structures may have a logic low level. Among the wordline electrodes of the uppermost level, the boost voltage VPP may be applied to the select wordline electrode through the turned-on main select transistor MST, and the ground voltage may be applied to the other wordline electrodes.

Among the plurality of inverted contact structures 4931-4938, the inverted contact structure 4941 connected to the select wordline electrode may have a logic low level, and the other inverted contact structures 4942-4948 may have a logic high level. The complementary select transistor CST connected to the wordline electrodes positioned at an uppermost level may be turned off, and connection between the select wordline electrode and the ground voltage may be cut off. The complementary select transistor CST connected to the wordline electrodes positioned at levels other than the uppermost level may be turned on, and the ground voltage applied to the ground select line structures 461 may be applied to the wordline electrodes through the complementary select transistor CST.

The memory device may include a plurality of memory cell structures. In some example embodiments, a plurality of memory cell structures may share at least a portion of the select lines, and integration efficiency of the memory device may be further increased or improved.

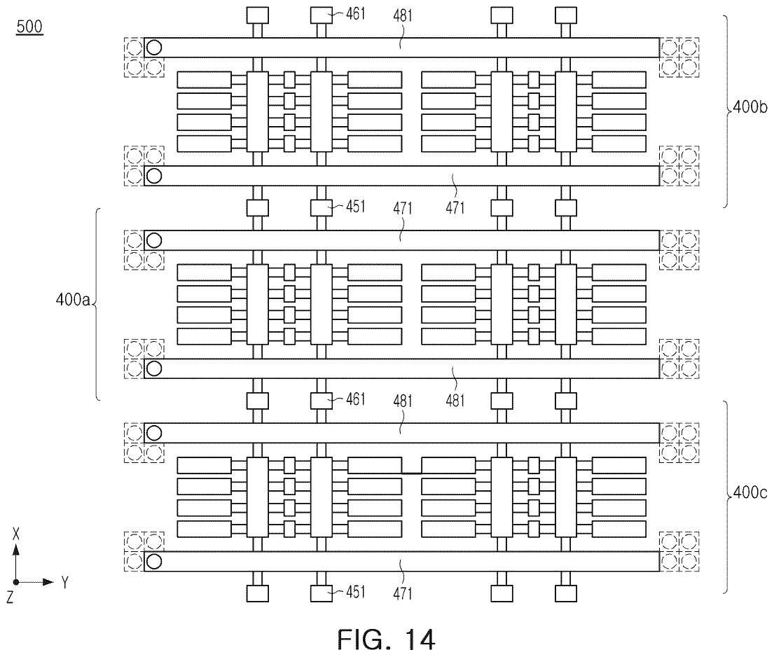

FIG. 14 is a diagram illustrating a layout 500 of a memory cell structure according to some example embodiments.

Referring to FIG. 14, the layout 500 may include a plurality of memory cell structures 400a, 400b, and 400c. The first memory cell structure 400a in FIG. 14 may be the same as or similar in some respect to the structure of the memory cell structure 400a described with reference to FIGS. 11 to 13. The second and third memory cell structures 400b and 400c may have structures in contact with the memory cell structure 400a in the first direction X and symmetrical in the first direction X.

According to some example embodiments, the first and second memory cell structures 400a and 400b, adjacent to each other, may share sub-select line structures 451, and the first and third memory cell structures 400a and 400c, adjacent to each other, may share ground select line structures 461.

In some example embodiments, each of the first to third memory cell structures 400a, 400b, and 400c may include a plurality of memory cells arranged in the first direction X, the second direction Y, and the third direction Z, a plurality of bitline structures connected to the plurality of memory cells and extending in a third direction Z, and a plurality of wordline structures extending in the first direction X and connected to the plurality of memory cells.

Sub-select line structures 451 may extend in the third direction Z between the first wordline structures of the first memory cell structure 400a and the second wordline structures of the second memory cell structure 400b. Main select line electrodes 471 extending in the second direction Y may be disposed between the sub-select line structures 451 and the first wordline structures, and main select line electrodes 471 extending in the second direction Y may be disposed between the sub-select line structures 451 and the second wordline structures.

Ground select line structures 461 may extend in the third direction Z between the first wordline structures of the first memory cell structure 400a and the third wordline structures of the third memory cell structure 400c. Inverted select line electrodes 481 extending in the second direction Y may be disposed between the ground select line structures 461 and the first wordline structures, and inverted select line electrodes 481 extending in the second direction Y may be disposed between the ground select line structures 461 and the third wordline structures.

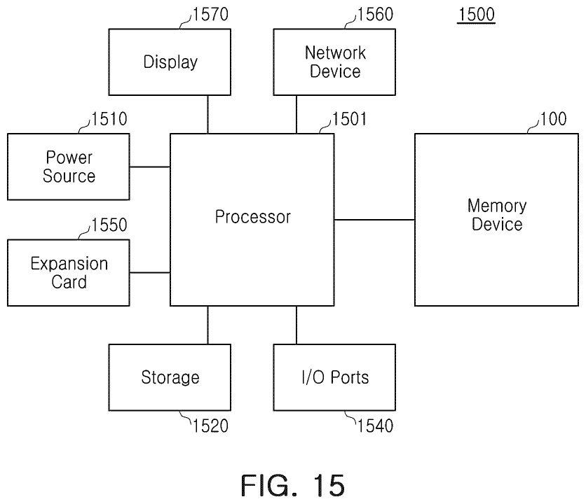

FIG. 15 illustrates an electronic system 1500 that includes the memory device 100, according to some example embodiments. In some example embodiments, the electronic system 1500 may include the memory devices 200 and/or 300 discussed above with reference to FIGS. 3 and 4 instead of or in addition to the memory device 100. In some example embodiments, the electronic system 1500 may include a plurality of memory devices 100. As illustrated, the electronic system 1500 may include a processor 1501 communicably coupled to the memory device 100. The electronic system 1500 may be implemented as a personal computer (PC), a data server or a portable electronic device. The portable electronic device may be implemented as a laptop computer, a mobile phone, a smartphone, a tablet PC, a personal digital assistant (PDA), an enterprise digital assistant (EDA), a digital still camera, a digital video camera, a portable multimedia player (PMP), a personal navigation device (PND), a handheld game console, a mobile Internet device (MID) or an e-book.

The electronic system 1500 may further include a power source 1510, a storage 1520, input/output ports 1540, an expansion card 1550, a network device 1560, and/or a display 1570.

The processor 1501 may control an operation of one or more of the memory device 100, the power source 1510, the storage 1520, the input/output ports 1540, the expansion card 1550, the network device 1560, and the display 1570. The power source 1510 may supply an operating voltage to one or more of the memory device 100, the storage 1520, the input/output ports 1540, the expansion card 1550, the network device 1560, and the display 1570. The storage 1520 may be implemented as a hard disk drive or a solid state drive (SSD). The memory device 100 may store a program code for controlling the operation of the processor 1501 or as a volatile memory for storing data.

Input/output ports 1540 may transmit data to the electronic system 1500 or transmit data output from the electronic system 1500 to an external device. For example, the input/output ports 1540 may be a port for access of a pointing device such as a computer mouse and a touch pad, a port for access of an output device such as the display 1570 or a printer, a port for access of an input device such as a keypad or a keyboard, or a port for access of a USB flash drive.

The expansion card 1550 may be implemented as a secure digital (SD) card, a multimedia card (MMC), or an eMMC. According to some example embodiments, the expansion card 1550 may be a subscriber identity module (SIM) card or a universal subscriber identity module (USIM) card.

The network device 1560 may be a device for connecting the electronic system 1500 to a wired or wireless network for communication between the electronic system 1500 and external devices.

The display 1570 may display data output from the storage 1520, the memory device 100, the input/output ports 1540, the expansion card 1550 and/or the network device 1560.

According to some example embodiments, since select lines may be shared between adjacent memory cell structures in the first direction X, the number of select lines disposed in the first semiconductor layer to drive wordlines may be reduced, and the number of contact structures for connecting select lines of the first semiconductor layer and driver circuits of the second semiconductor layer may be reduced. Accordingly, the area of the memory device may be reduced.

According to some example embodiments, a memory device may select a wordline based on two types of wordline select signals, and such a configuration may reduce the area occupied by driver circuits for driving the wordline.

Also, in the memory device, according to some example embodiments, select lines for transferring a wordline select signal may be disposed in a first semiconductor layer including a three-dimensional memory cell structure, and the area occupied by contact structures for connecting wordlines and driver circuits may be reduced.

As described herein, any devices, systems, modules, portions, units, controllers, circuits, and/or portions thereof according to any of the example embodiments, and/or any portions thereof (including, without limitation, the control logic circuit 210, the address register 221, the bank control circuit 222, the refresh counter 223, the row address multiplexer 224, the column address latch 225, the row decoder 226, the column decoder 227, the bank array 241, the sense amplifier 242, the input/output gate circuit 243, the data input/output buffer 250, the bank array 310, the row decoder 320, the column decoder 330, the processor 1501, any portion thereof, or the like) may include, may be included in, and/or may be implemented by one or more instances of processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a graphics processing unit (GPU), an application processor (AP), a digital signal processor (DSP), a microcomputer, a field programmable gate array (FPGA), and programmable logic unit, a microprocessor, application-specific integrated circuit (ASIC), a neural network processing unit (NPU), an Electronic Control Unit (ECU), an Image Signal Processor (ISP), and the like. In some example embodiments, the processing circuitry may include a non-transitory computer readable storage device (e.g., a memory), for example a solid state drive (SSD), storing a program of instructions, and a processor (e.g., CPU) configured to execute the program of instructions to implement the functionality and/or methods performed by some or all of any devices, systems, modules, portions, units, controllers, circuits, and/or portions thereof according to any of the example embodiments.

Any of the elements and/or functional blocks disclosed above may include or be implemented in processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc. The processing circuitry may include electrical components such as at least one of transistors, resistors, capacitors, etc. The processing circuitry may include electrical components such as logic gates including at least one of AND gates, OR gates, NAND gates, NOT gates, etc.

While several embodiments have been provided in the present disclosure, it should be understood that the disclosed systems and methods might be embodied in many other specific forms without departing from the spirit or scope of the present disclosure. The present examples are to be considered as illustrative and not restrictive, and the intention is not to be limited to the details given herein. For example, the various elements or components may be combined or integrated in another system or certain features may be omitted, or not implemented.

What is claimed is:

1. A memory device, comprising:
a first semiconductor layer including,
a plurality of memory cells in a first direction, a second direction, and a third direction orthogonal to each other,
a plurality of bitlines connected to the plurality of memory cells,
a plurality of wordlines connected to the plurality of memory cells,
a plurality of main wordline select lines,
a plurality of inverted wordline select lines,
a plurality of sub-wordline select lines,
a plurality of ground select lines,
a plurality of main select transistors, each of the plurality of main select transistors having a drain connected to a corresponding one of the plurality of sub-wordline select lines, a source connected to a corresponding one of the plurality of wordlines, and a gate connected to a corresponding one of the plurality of main wordline select lines, and
a plurality of complementary select transistors, each of the plurality of complementary select transistors having a drain connected to a corresponding one of the plurality of wordlines, a source connected to a corresponding one of the plurality of ground select lines, and a gate connected to a corresponding one of the plurality of inverted wordline select lines; and
a second semiconductor layer including,
a plurality of first driver circuits configured to drive the plurality of sub-wordline select lines,
a plurality of second driver circuits configured to drive the plurality of main wordline select lines, and
a plurality of third driver circuits configured to drive the plurality of inverted wordline select lines, wherein the second semiconductor layer is on the first semiconductor layer in the third direction.

2. The memory device of claim 1, wherein the second semiconductor layer further includes a row decoder configured to control the plurality of first driver circuits based on first bits of a row address and configured to control the plurality of second driver circuits and the plurality of third driver circuits based on second bits of the row address.

3. The memory device of claim 2, wherein, the row decoder is configured to drive a selected wordline with a boost voltage by driving a first sub-wordline select line connected to the selected wordline with the boost voltage, driving a first main wordline select line connected to the selected wordline with the boost voltage, and driving a first inverted wordline select line corresponding to the selected wordline with a ground voltage.

4. The memory device of claim 3, wherein, the row decoder is configured to drive non-selected wordlines with the ground voltage by driving sub-wordline select lines other than the first sub-wordline select line among the plurality of sub-wordline select lines with the ground voltage, driving main wordline select lines other than the first main wordline select line among the plurality of main wordline select lines with the ground voltage, and driving inverted wordline select lines other than the first inverted wordline select line among the plurality of inverted wordline select lines with the boost voltage.

5. The memory device of claim 1,
wherein the plurality of bitlines extend in the third direction and are in the first direction and the second direction, and
wherein the plurality of wordlines extend in the first direction and are in the second direction and the third direction.

6. The memory device of claim 5,
wherein the plurality of sub-wordline select lines extend in the third direction and are apart from the plurality of wordlines in the first direction,
wherein the plurality of main wordline select lines extend in the second direction and are between the plurality of sub-wordline select lines and the plurality of wordlines,
wherein the plurality of ground select lines extend in the third direction, and the plurality of ground select lines and the plurality of sub-wordline select lines are disposed in opposite directions with respect to the plurality of wordlines, and
wherein the plurality of inverted wordline select lines extend in the second direction, and are between the plurality of ground select lines and the plurality of wordlines.

7. The memory device of claim 5, wherein at least a portion of the plurality of wordlines have a same length.

8. A memory device, comprising:
a substrate;
a memory cell structure including,
a plurality of bitline structures extending in a vertical direction through a plurality of levels defined in the vertical direction perpendicular to an upper surface of the substrate,
a plurality of memory cells in contact with sidewalls of the plurality of bitline structures at the plurality of levels, and
a plurality of wordline structures extending in a first direction parallel to the upper surface of the substrate at the plurality of levels and connected to the plurality of memory cells;
a plurality of first select line structures spaced apart from the plurality of wordline structures in the first direction and extending in the vertical direction;
a plurality of second select line structures extending in a second direction parallel to the upper surface of the substrate and intersecting the first direction between the plurality of first select line structures and the plurality of wordline structures;
a plurality of first channel structures in contact with the plurality of first select line structures and the plurality of wordline structures and penetrating the plurality of second select line structures;
a plurality of third select line structures opposite to the plurality of first select line structures with respect to the plurality of wordline structures and extending in the vertical direction;
a plurality of fourth select line structures extending in the second direction between the plurality of third select line structures and the plurality of wordline structures; and
a plurality of second channel structures in contact with the plurality of third select line structures and the plurality of wordline structures and penetrating the plurality of fourth select line structures.

9. The memory device of claim 8, further comprising:
a plurality of first driver circuits connected to the plurality of first select line structures;
a plurality of second driver circuits connected to the plurality of second select line structures;
a ground power connected to the plurality of third select line structures; and
a plurality of third driver circuits connected to the plurality of fourth select line structures.

10. The memory device of claim 8, further comprising:
an insulating layer covering the memory cell structure, the plurality of first select line structures, the plurality of second select line structures, the plurality of third select line structures, the plurality of fourth select line structures, and the plurality of first and second channel structures on the upper surface of the substrate.

11. The memory device of claim 10,
wherein each of the plurality of second select line structures includes an upper surface that is offset from other second select line structures in the vertical direction, and
wherein the memory device further includes a plurality of first contact structures extending from the upper surfaces of the plurality of second select line structures to an upper surface of the insulating layer.

12. The memory device of claim 11, wherein the plurality of first contact structures are in the first direction and the second direction on a plane parallel to the upper surface of the substrate.

13. The memory device of claim 8,
wherein the plurality of first channel structures include a first impurity region in contact with the plurality of first select line structures, a second impurity region in contact with the plurality of wordline structures and a channel region surrounded by the plurality of second select line structures, and
wherein the plurality of second channel structures include a first impurity region in contact with the plurality of third select line structures, a second impurity region in contact with the plurality of wordline structures and a channel region surrounded by the plurality of fourth select line structures.

14. The memory device of claim 8,
wherein each memory cell of the plurality of memory cells includes:
a cell capacitor, and
a cell transistor connecting the cell capacitor to one of the plurality of bitline structures,
wherein, among the plurality of memory cells, the memory cells in the first direction are connected to corresponding one of the plurality of wordline structures.

15. The memory device of claim 14, wherein the cell transistor includes:
a third channel structure penetrating the corresponding one of the plurality of wordline structures and connected to the cell capacitor and the one of the plurality of bitline structures, and
a region surrounding the third channel structure in the corresponding one of the plurality of wordline structures.

16. The memory device of claim 15, wherein the plurality of first channel structures, the plurality of second channel structures and the third channel structure have a same size and a same shape.

17. A memory device, comprising:
a first memory cell structure including a plurality of first memory cells in a first direction, a second direction, and a third direction orthogonal to each other, a plurality of first bitlines extending in the third direction and connected to the plurality of first memory cells, and a plurality of first wordlines extending in the first direction and connected to the plurality of first memory cells;
a second memory cell structure including a plurality of second memory cells in the first direction, the second direction and the third direction, a plurality of second bitlines extending in the third direction and connected to the plurality of second memory cells, and a plurality of second wordlines extending in the first direction and connected to the plurality of second memory cells;
a plurality of sub-select line structures extending in the third direction between the plurality of first wordlines and the plurality of second wordlines;
a plurality of first main select line structures extending in the second direction between the plurality of first wordlines and the plurality of sub-select line structures;
a plurality of second main select line structures extending in the second direction between the plurality of second wordlines and the plurality of sub-select line structures;
a plurality of first channel structures penetrating the plurality of first main select line structures and connecting the plurality of first wordlines to the plurality of sub-select line structures; and
a plurality of second channel structures penetrating the plurality of second main select line structures and connecting the plurality of second wordlines to the plurality of sub-select line structures.

18. The memory device of claim 17, further comprising:
a plurality of ground select line structures opposite to the plurality of sub-select line structures with respect to the plurality of first wordlines and extending in the third direction; and
a plurality of first inverted select line structures extending in the second direction between the plurality of ground select line structures and the plurality of first wordlines.

19. The memory device of claim 18, further comprising:
a third memory cell structure including a plurality of third memory cells in the first direction, the second direction and the third direction, a plurality of third bitlines extending in the third direction and connected to the plurality of third memory cells, and a plurality of third wordlines extending in the first direction and connected to the plurality of third memory cells; and
a plurality of second inverted select line structures extending in the second direction between the plurality of ground select line structures and the plurality of third wordlines.

20. The memory device of claim 17,
wherein each of the plurality of first main select line structures includes an upper surface that is offset from or not overlapping other first main select line structures in the third direction, and
wherein the memory device further includes contact structures extending in the third direction on the upper surface of each of the plurality of first main select line structures.
